(19) United States
(12) Patent Application Publication
(10) Pub. No.: US 2002/0121669 A1
(43) Pub. Date: Sep. 5, 2002

(54) Organic superconductive field-effect switching device

(76) Inventors: Bertham Josef Batlogg, Murray Hill, NJ (US); Christian Kloc, South Orange, NJ (US); Jan Hendrik Schon, Summit, NJ (US)

Correspondence Address: Docket Administrator (Room 3J-219), Lucent Technologies Inc., 101 Crawfords Corner Road, Holmdel, NJ, 07733-3030, US

(21) Appl. No.: 10/050,729

(22) Filed: Jan. 16, 2002

Related U.S. Application Data
(63) Continuation-in-part of application No. 09/560,729, filed on Apr. 28, 2000, now abandoned.

(51) Int. Cl. H01L 29/76

(52) U.S. Cl. 257/393

(57) ABSTRACT

Disclosed is a field-effect switch that uses an applied field to induce superconductivity in a normally insulative switch element. The switch element comprises an intercalated crystal of C₆₀ together with a further species such as a methylene trihalide. Using such a switch element, we have obtained field-induced superconducting transitions at temperatures well above 77K.

### CROSS-REFERENCE TO RELATED APPLICATION

This application contains subject matter related to the commonly assigned, co-pending U.S. patent application Ser. No. 09/990,212, filed on Nov. 21, 2001 by B. J. Batlogg et al. under the title “Organic Solid-State Switching Device” as a Continuation-in-Part of the commonly assigned U.S. patent application Ser. No. 09/560,729, filed by the same inventors on Apr. 28, 2000.

### FIELD OF THE INVENTION

This invention relates to solid-state electronic switching devices. More specifically, the invention relates to switching devices that can be made to undergo a superconductive transition in response to an applied electric field.

### ART BACKGROUND

It has long been fundamental in the control of electric currents to switch an element between a relatively insulative and a relatively conductive state by applying an electric field or electrical potential. Demands have grown for switching devices that respond ever more quickly to ever lower activating power levels. Such demands have driven a search for new switching technologies.

One promising approach to fast, low-power switching is based on the properties of superconductive materials. Superconductive materials are of particular interest because if a superconductive transition can be made to occur in response to a control signal, the resulting complete loss of electrical resistance in the switch element provides ideal, or nearly ideal, switch behavior.

Practitioners have, in fact, studied the effects of static electric fields on superconductivity in certain materials. For example, the article R. E. Glover et al., Phys. Rev. Lett. 5 (1960) 248 describes one such study in materials that are metals at room temperature. The articles J. Mannhart et al., Appl. Phys. Lett. 62 (1993) 630 and J. Mannhart et al., J. Alloys Compd. 195 (1993) 519 describe studies carried out on inorganic cuprate films belonging to the class of materials popularly referred to as “high-temperature superconductors.” These materials are typically non-metallic at room temperature, but they are also generally poor insulators. That is, they are typically doped to induce room-temperature electrical conductivities greater than 10⁻⁵ siemens/cm.

In the Mannhart studies, static applied electric fields were used to induce shifts in the superconducting transition temperature of such inorganic cuprate films. However, it is only recently that an applied electric field was shown to induce complete switching between a superconducting state and an insulating state of a switch element.

Co-pending U.S. patent application Ser. No. 09/990,212, cited above, discloses a field-effect switch that uses an applied field to induce superconductivity in a switch element. The switch element comprises an organic material that has no superconducting transition in the absence of applied electric fields. In specific embodiments, such organic material is electrically insulative at least at cryogenic temperatures.

Those skilled in the art have recognized that still greater advantages can be realized in superconductive field-effect switching devices by shifting the superconducting transitions in such devices to higher temperatures.

### SUMMARY OF THE INVENTION

We have found that intercalated C₆₀ materials are useful for making superconductive field-effect devices having relatively high critical temperatures for the superconducting transition. More specifically, we have identified several intercalated C₆₀ materials having field-induced superconducting transitions at temperatures greater than the boiling point of nitrogen, i.e., greater than 77K.

Accordingly, the invention in one embodiment involves a device comprising a substrate and an FET electrode arrangement formed on the substrate. The FET electrode arrangement includes source, drain, and gate electrodes and a further-layer, situated between the substrate and the gate electrode, that is more insulative than the substrate. The substrate comprises material having a crystal structure in which C₆₀ is intercalated with at least one further molecular species such that at least one lattice constant of the crystal structure is greater than the corresponding lattice constant of pure C₆₀. The intercalated C₆₀ material is of a kind that has no superconducting transition in the absence of applied electric fields, but is capable of becoming superconducting in a portion of the substrate at temperatures below a critical temperature when the FET electrode arrangement is operated so as to inject at least a minimum density of carriers into the substrate.

### BRIEF DESCRIPTION OF THE DRAWING

FIG. 1 is a schematic drawing of a switching device according to the invention in one embodiment.

FIG. 2 is a schematic drawing of a Josephson junction device, according to the invention in an alternate embodiment.

FIG. 3 is a graph of channel resistance as a function of temperature for devices of the kind depicted in FIG. 1. Represented in the upper part of the figure is a device in which the switch element comprises C₆₀ intercalated with methylene tribromide. Represented in the lower part of the figure are devices in which the switch element comprises, respectively, C₆₀, C₆₀ intercalated with methylene trichloride, and C₆₀ intercalated with methylene tribromide.

### DETAILED DESCRIPTION

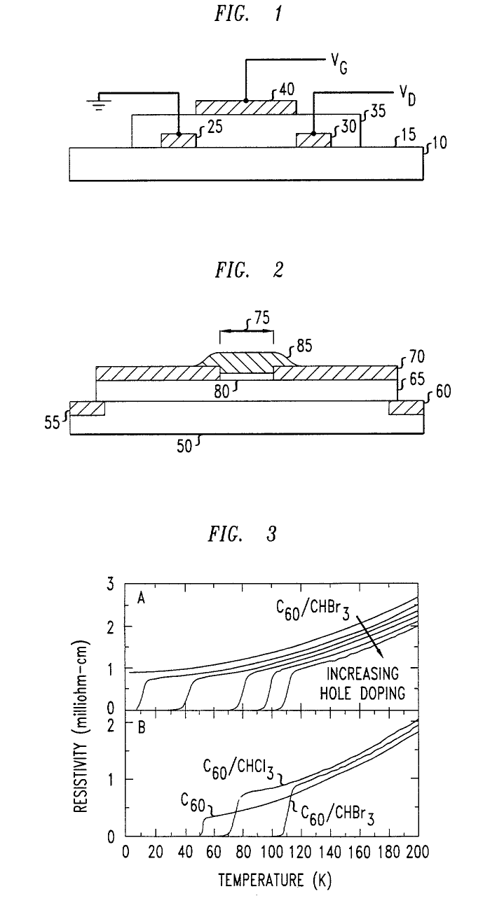

An illustrative switching device is schematically illustrated in FIG. 1. Organic insulative body 10 is exemplarily a single crystal of an organic compound that, in the absence of applied electric fields, has no superconducting transition when pure, but which becomes superconductive at appropriate temperatures and doping levels. In earlier studies, we successfully demonstrated devices of the kind illustrated in FIG. 1, in which body 10 comprises, inter alia, C₆₀, C₇₀, pentacene, or tetracene. According to the principles of the present invention, body 10 comprises an intercalated C₆₀ crystal, as will be described in greater detail below.

Source electrode 25 and drain electrode 30 are exemplarily formed on face 15 of body 10 by thermally evaporating an appropriate metallic material such as gold through a shadow mask that defines, e.g., a channel length of 25-50 μm and a channel width of 500-1000 μm. As those skilled in the art will appreciate, low work-function metals are preferred for devices in which the injected carriers are electrons. Aluminum is another appropriate material for the source and drain electrodes. However, aluminum undergoes its own superconducting transition at low temperatures. We chose to use gold instead of aluminum so that our observations of superconductivity would not be obscured by the aluminum superconducting transition.

We did not anneal the device after forming the source and drain electrodes, because our intercalated material was found to be unstable above about 90 C.

Gate dielectric layer 35 is preferably composed of a material whose electrical breakdown strength is greater than the gate field to be applied during device operation, and whose electrical resistivity exceeds that of body 10 by a great enough margin to assure that carrier injection takes place in the channel region of the device. Layer 35 is referred to as a “dielectric” layer in keeping with standard terminology in the MOS fabrication arts, and not to limit the choice of materials from which it may be formed. Exemplarily, dielectric layer 35 substantially comprises sputter-deposited amorphous alumina (Al₂O₃) having a capacitance of about 185 nF-cm⁻². Layer 35 is deposited so as to overlie source electrode 25, drain electrode 30, and the intervening channel portion of face 15. Gate electrode 40 is deposited by conventional methods so as to overlie dielectric layer 35 and the corresponding channel portion of face 15. The gate electrode exemplarily comprises vapor-deposited gold.

In an exemplary mode of operating the device of FIG. 1, the device is cooled to below its critical temperature. To induce the superconducting state in the channel portion of the device, a potential of at least the critical gate voltage is applied to gate electrode 40. The gate voltage V_{G} is typically defined relative to the potential on source electrode 25.

The critical gate voltage varies somewhat with the specific operating temperature, but even for extremely low temperatures it must be above a threshold value. By way of illustration, we have estimated that for a pure C₆₀-based device operating by electron induction, the critical gate voltage at the maximum critical temperature of 11K is the positive voltage needed to induce an areal charge density of electrons in the channel region of 2.7×10¹³ cm⁻², which corresponds to a density of three electrons per molecule of C₆₀. Similarly, for a pure C₆₀-based device operating by hole induction, the critical gate voltage at the maximum critical temperature of 52K is the negative voltage needed to induce a hole density in the channel region of 3-3.5 holes per molecule of C₆₀.

The specific voltage required to induce such an areal charge density depends upon the capacitance of the gate electrode and the thickness of dielectric layer 35. In our device, superconductivity was achieved at the maximum critical temperature at a typical applied gate voltage of approximately 200 V.

By way of illustration, our switching device can be operated with a potential difference between source and drain of, e.g., about one volt or less. We have estimated that a current on the order of nanoamperes can flow between the source and the drain without reaching the critical current density at which superconductivity ceases and normal conductivity returns. With larger-area devices, concomitantly larger currents can be supported.

It should be noted that the switching device of FIG. 1 is merely illustrative, and that the principles of the present invention are also applicable to other types of electronic devices.

One such device is a Josephson junction device as illustrated, e.g., in FIG. 2. As seen in the figure, an illustrative such device includes an organic crystal substrate 50, source electrode 55, and drain electrode 60, all substantially as described above. Lower gate dielectric layer 65 is deposited on the organic substrate, exemplarily by sputtering. Lower gate electrode layer 70 is then deposited, exemplarily by shadow evaporation. Importantly, layer 70 is formed as two portions separated by gap 75. Then, upper gate dielectric layer 80 is deposited over a region that includes gap 75. Then, upper gate electrode layer 85 is deposited over layers 70 and 80 such that upper gate electrode layer 85 is electrically continuous with lower gate electrode layer 70.

By appropriate adjustment of the gate voltage applied to gate electrode layers 70 and 85, it is possible to achieve a spatial variation of the induced carrier concentration, leading at appropriate temperatures to the formation of superconductor-normal-superconductor structure, in which the normally conductive region is the portion of the channel lying below gap 75.

Turning again to FIG. 1, body 10 according to the principles of the present invention comprises material having a crystal structure in which C₆₀ is intercalated with at least one further molecular species such that at least one lattice constant of the crystal structure is greater than the corresponding lattice constant of pure C₆₀.

For example, we have found that when the C₆₀ lattice is expanded by intercalation with, e.g., methylene trichloride (CHCl₃) or methylene tribromide (CHBr₃), critical temperatures substantially higher than 77K can be achieved.

To form the intercalated crystals, we first grew undoped C₆₀ from the vapor phase in a stream of hydrogen by the technique described, e.g., in C. Kloc, et al., “Physical vapor growth of centimeter-sized crystals of α-hexathiophene,” J. Crystal Growth 182 (1997) 416-427. The starting material for the vapor-phase growth was purified by multiple, e.g., triple, sublimation. Typical crystals of C₆₀ produced by the vapor-phase growth are several cubic millimeters in volume and of roughly equal extent in all three dimensions.

Methylene trichloride or tribromide was intercalated into the C₆₀ by one of two methods. According to one method, crystals were grown from a solution containing chloroform or bromoform. When the temperature of the solution is lowered, the material begins to nucleate, and small crystals are formed. This technique is described in detail in M. Jansen, et al., “Synthesis and Characterization of the Fullerene Co-Crystals C₆₀-12C₆H₁₂, C₇₀-12C₆H₁₂, C₆₀-12CCl₄, C₆₀-2CHBr₃, C₆₀-2CHCl₃, C₆₀-2H₂CCl₂,” Z. Anorg. Allg. Chemie 621 (1995) 14-18. The resulting co-crystals exhibited a hexagonal crystal structure. The lattice expansion was found to correspond to a cubic lattice constant of about 14.28 Å for the trichloride and about 14.43 Å for the tribromide.

According to an alternative method, pure single crystals of C₆₀ are dipped into chloroform or bromoform. As a consequence, the surface region of the dipped crystal dissolves slightly. Then, the temperature is lowered. This causes an intercalated crystal to grow over the crystal of pure C₆₀. Because field-induced electron- or hole-doping affects only the surface region, the crystals obtained by this alternative method will exhibit the desired switching behavior in the context of the present invention.

Using the intercalated crystals, we fabricated field-effect transistors substantially as described above with respect to FIG. 1. The occurrence of ambipolar transport showed that the intercalated methylene trihalide species did not contribute severe hole-trapping or significant electron doping. However, there did result an increase of residual resistivity. For example, material that was electron-doped to about three electrons per C₆₀ exhibited a residual resistivity in the range 500-650 μΩ-cm, whereas in undoped C₆₀ the corresponding range is 250-300 μΩ-cm.

Studies on bulk samples of C₆₀ doped with alkali metals (i.e., A₃C₆₀, where A denotes an alkali metal) have shown that these superconductors exhibit a trend toward higher transition temperature with greater lattice expansion. See, e.g., O. Gunnarson, Rev. Mod. Phys. 69 (1997) 575. For that reason, we believe that within the context of the present invention, it is likely that transition temperatures can be increased still further by the judicious selection of further species, beyond those mentioned above, for intercalation with C₆₀.

Appropriate species for intercalation will most likely be neutral organic molecules that act as spacers without interacting chemically with the constituent C₆₀ molecules. It will be desirable for the intercalant species to be nearly spherical in order to preserve the crystal structure and symmetry. It should be noted, however, that this cannot be a strict requirement, since the molecules of methylene trichloride and methylene tribromide are somewhat aspherical and induce a slight hexagonal distortion of the crystal structure. Because hole doping gives the highest critical temperatures, and thus is the preferred mechanism for inducing the superconducting transition, it is also advantageous to select an intercalant species that does not donate electrons.

### EXAMPLE

FIG. 3 shows a group of plots of channel resistance versus temperature for field-effect devices of the kind depicted in FIG. 1. The upper portion of the figure, denoted “A,” shows a series of plots for a device in which the switched element comprises C₆₀ intercalated with methylene tribromide. As indicated by an arrow in the figure, the level of hole doping increases from the upper left toward the bottom right of the figure. The highest level of hole doping represented in the figure is 3.2 holes per molecule of C₆₀. It is evident from the figure that at that level of hole doping, the onset of superconductivity occurs at 117K, and the main drop in resistance begins at 115K.

The lower portion of FIG. 3, denoted “B,” shows plots of channel resistance versus temperature for three devices, in which the switched element comprises, respectively, C₆₀, C₆₀ intercalated with methylene trichloride, and C₆₀ intercalated with methylene tribromide. All three curves are for optimal hole doping; i.e., for that hole concentration which yields the highest superconducting transition temperature.

We observed superconductivity above 1.7K when the hole density rose to about one hole per molecule of C₆₀. The value of the superconducting transition temperature was found to increase with the size of the intercalant molecule and with the hole concentration. The highest transition temperature that we observed was 117K, under the conditions noted above. When we electron-doped the intercalated material, we observed superconductivity only in the range of about 2.5-3.5 electrons per C₆₀ molecule, whereas for hole doping, superconductivity was observed at a doping level as low as about one hole per C₆₀ molecule.

1. A device, comprising:
a) a substrate; and
b) an FET electrode arrangement formed on the substrate, said arrangement comprising source, drain, and gate electrodes and a further layer, situated between the substrate and the gate electrode, that is more insulative than the substrate,
and wherein:
c) the substrate comprises material having a crystal structure in which C₆₀ is intercalated with at least one further molecular species such that at least one lattice constant of the crystal structure is greater than the corresponding lattice constant of pure C₆₀; and
d) said material has no superconducting transition in the absence of applied electric fields, but said material is capable of becoming superconducting in a portion of the substrate at temperatures below a critical temperature when the FET electrode arrangement is operated so as to inject at least a minimum density of carriers into the substrate.

2. The device of claim 1, wherein at least one said further molecular species is a methylene trihalide.

3. The device of claim 2, wherein said methylene trihalide is methylene trichloride.

4. The device of claim 2, wherein said methylene trihalide is methylene tribromide.

5. The device of claim 1, wherein the FET electrode arrangement comprises a lower gate electrode divided by a gap into a portion proximate the source electrode and a portion proximate the drain electrode, and an upper gate electrode electrically continuous with the lower gate electrode, and wherein:
the upper gate electrode overlies the gap but is separated therefrom by an intervening layer of material more insulative than the material of the upper and lower gate electrodes; and
at temperatures below a critical temperature, the FET electrode arrangement, when suitably energized, is operable to induce the formation of at least one Josephson junction in the substrate material.

6. A method, comprising:
at a temperature less than or equal to a critical temperature, operating an FET electrode arrangement formed on a substrate comprising a material having a crystal structure in which C₆₀ is intercalated with at least one further molecular species such that at least one lattice constant of the crystal structure is greater than the corresponding lattice constant of pure C₆₀, thereby to induce superconductivity in at least a portion of the substrate material.

7. The method of claim 6, wherein at least one said further molecular species is a methylene trihalide.

8. The method of claim 7, wherein said methylene trihalide is methylene trichloride.

9. The method of claim 7, wherein said methylene trihalide is methylene tribromide.

10. The method of claim 6, further comprising passing an electric current through the superconductive portion of the substrate material between a source region and a drain region of said material.

11. The method of claim 10, further comprising operating the FET electrode arrangement so as to produce intermittent superconductivity in the substrate material, thereby to modulate the electric current passing between the source and drain regions.

12. The method of claim 6, wherein the operation of the FET electrode arrangement comprises applying to a gate electrode a voltage having a polarity effective for inducing a surplus population of electrons in at least a portion of the substrate material.

13. The method of claim 6, wherein the operation of the FET electrode arrangement comprises applying to a gate electrode a voltage having a polarity effective for inducing a surplus population of holes in at least a portion of the substrate material.

14. The method of claim 6, wherein: the FET electrode arrangement comprises a gate electrode arrangement operable for inducing a surplus population of electrons or holes in the substrate material; the gate electrode arrangement is configured to have a relatively strong inductive effect in portions of the substrate material proximate a source region and a drain region thereof, and a relatively weak inductive effect in a portion of the substrate material intermediate said strongly induced portions; and the operation of the FET electrode arrangement is carried out so as to induce superconductivity in said strongly induced portions without concurrent superconductivity in said weakly induced portion, leading to the formation of at least one Josephson junction in the substrate material.
